(19) United States
(12) Patent Application Publication
(10) Pub. No.: US 2008/0164898 A1
(43) Pub. Date: Jul. 10, 2008

(54) Probe card for test of semiconductor chips and method for test of semiconductor chips using the same

(75) Inventors: Sung-Hoon Bae, Hwaseong-si (KR); Jung-Hyeon Kim, Hwaseong-si (KR); Young-Soo An, Yongin-si (KR); Ho-Jeong Choi, Yongin-si (KR); Myoung-Sub Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/005,888

(22) Filed: Dec. 28, 2007

(30) Foreign Application Priority Data
Jan. 4, 2007 (KR) 10-2007-0001010

(51) Int. Cl. G01R 31/02

(52) U.S. Cl. 324/758

(57) ABSTRACT

There are provided a probe card for test of semiconductor chips and a method for testing semiconductor chips using the probe card. In implementing the probe card for electrically testing semiconductor chips, the probe blocks corresponding to multiple selected ones of the semiconductor chips on the wafer can be selected so that the selected semiconductor chips are EDS tested in a one-step process. As the selected semiconductor chips are EDS tested in a one-step process, equipment efficiency is improved, and statistical objectivity of data indicating characteristics of the wafer can be achieved.

### CROSS-REFERENCE TO RELATED APPLICATION

This application claims priority under 35 U.S.C. 119 to Korean Patent Application No. 10-2007-0001010, filed Jan. 4, 2007, the disclosure of which is hereby incorporated herein by reference in its entirety.

### BACKGROUND OF THE INVENTION

1. Technical Field

The present invention relates to a probe card for testing semiconductor chips and a method for testing semiconductor chips using the probe card, and more particularly, to a probe card capable of testing any of the semiconductor chips on a wafer and a method for testing semiconductor chips using the probe card.

2. Discussion of Related Art

In recent years, with the rapid development of information communications and rapid popularization of information media, such as computers, semiconductor devices have been rapidly developed. Accordingly, high-speed and high-capacity semiconductor devices are required. Due to high integration and high capacity of semiconductor devices, unit elements constituting a memory cell are scaled down, and a high-integration technique to form a multi-layered structure within a limited area is dramatically advanced.

For this high-integration, high-accuracy and precision unit processes are required to fabricate semiconductor devices. Typically, unit processes include a process of implanting and diffusing group 3B impurity ions (e.g., B) or group 5B impurity ions (e.g., P or As) into a semiconductor substrate, a deposition process of forming a material film on the semiconductor substrate, an etching process, such as photolithography, for patterning the material film into a desired shape, a wafer cleaning process for eliminating impurities, such as a chemical mechanical polishing (CMP) process of polishing a surface of the wafer to eliminate a step after depositing an interlayer insulating film and the like on the surface of the wafer, and the like. These unit processes are selectively and repeatedly performed to stack a plurality of circuit patterns on the wafer surface for fabrication of the semiconductor device.

To complete a semiconductor integrated circuit using these unit processes, semiconductor devices on the wafer are divided into individual semiconductor dies by a blade in a sawing process. Specifically, in the sawing process, the wafer is entirely cut along a scribe line in one direction using the blade. A wafer chuck with the wafer mounted is rotated by 90° and the wafer is cut perpendicularly to the scribe line into semiconductor dies. In this wafer sawing process, however, semiconductor chips are divided, but they are also scattered to the exterior and unavailable when only the wafer is sawed. To prevent this, an adhesive tape is adhered to a rear surface of the wafer so that the semiconductor chips divided by sawing are kept aligned, and not scattered to the exterior. In a subsequent die attaching process, the divided chips are separated one by one and subjected to a packaging process in which the semiconductor chips are molded.

Meanwhile, prior to the packaging process, an electrical die sort (EDS) test is performed at a wafer level to test electrical characteristics of the semiconductor chips. Typically, in the EDS test, an electrical signal is applied to the unit chips on a wafer and a defective one of unit chips is detected based on a response signal.

To this end, a probe card with probe needles capable of getting in contact with the wafer and applying an electrical signal from test equipment to the wafer is required to check electrical states of chips on the wafer.

FIG. 1 illustrates a conventional single-type probe card 10. Referring to FIG. 1, the single-type probe card 10 comprises a circuit board 12 and a plate 14 for securing the circuit board 12. The circuit board 12 comprises a plurality of contact pads 16. The fixing plate 14 comprises a probe area 18 including a plurality of probe blocks 20. Each of the probe blocks 20 has a probe needle 22 for applying an electrical signal to a semiconductor chip.

A method for EDS test using the probe card 10 shown in FIG. 1 will be described. A semiconductor chip to be EDS tested is aligned between the probe card 10 and the tester so that it is located at a center of the probe card 10. An electrical signal generated from the tester is then applied to the probe needle 22 and the probe needle 22 is brought into contact with a probing pad on the semiconductor chip so that the electrical signal from the tester is derived to the semiconductor chip for EDS test.

With the single-type probe card 10, one semiconductor chip can be EDS tested. Accordingly, the EDS test can be exactly performed on the targeted semiconductor chip, but takes a relatively long time to test multiple semiconductor chips on the wafer.

To solve the problem of such significant time consumption, a technique of testing multiple semiconductor chips on the wafer at the same time has been recently proposed. A method for EDS test using a probe card for multi-chip test is one example of the technique of testing multiple semiconductor chips on the wafer at the same time.

FIG. 2 illustrates a conventional multi-type probe card 100. Referring to FIG. 2, the multi-type probe card 100 comprises a circuit board 102 and a fixing plate 104 for securing the circuit board 102. The circuit board 102 comprises a plurality of contact pads 106. The fixing plate 104 comprises five probe areas 108 divided by reinforcing guidelines 114. Each probe area 108 includes a probe block 110. The probe block 110 has probe needles 112 for applying an electrical signal to a semiconductor chip. The probe needles 112 of each probe block 110 correspond to respective probing pads of semiconductor chips formed on the wafer.

A method for an EDS test using the multi-type probe card 100 shown in FIG. 2 is similar to the method for an EDS test using the single-type probe card 10 shown in FIG. 1. That is, the semiconductor chip to be EDS tested is aligned between the multi-type probe card 100 and the tester so that it is located at a center of the multi-type probe card 100. An electrical signal generated from the tester is then applied to the probe needle 112 and the probe needle 112 is brought into contact with the probing pad on the semiconductor chip so that the electrical signal from the tester is supplied to the semiconductor chip for EDS test.

When the multi-type probe card 100 is used for EDS testing of semiconductor chips, five semiconductor chips can be EDS tested at a time using five probe blocks 110 with probe needles. Accordingly, EDS test time can be greatly shortened, unlike the single-type probe card 10 as shown in FIG. 1. For example, if the EDS test time of one semiconductor chip is one minute, the single-type probe card 10 shown in FIG. 1 takes five minutes to EDS test five semiconductor chips while the multi-type probe card 100 shown in FIG. 2 takes one minute.

As other examples, a probe card capable of EDS-testing a plurality of semiconductor chips at a time and a method for EDS test using the probe card are disclosed, for example, in Japanese Patent Laid-open Publication No. 2003-297887 and U.S. Patent Publication No. 2006-170437.

The above multi-type probe cards are useful for EDS testing a plurality of semiconductor chips located at defined positions. Accordingly, the multi-type probe cards are less efficient in EDS testing a plurality of semiconductor chips which are arbitrarily selected on a wafer in order to achieve statistical objectivity of data indicating characteristics of the wafer. With the multi-type probe cards disclosed in the Japanese Patent and the U.S. patent Publication noted above, as well as the probe card shown in FIG. 2, a plurality of semiconductor chips can be EDS tested efficiently at the same time using the plurality of probe blocks with the probe needles. However, the conventional multi-type probe cards can be used to test only semiconductor chips in a central area of the wafer. That is, the positions of semiconductor chips to be EDS tested are already designated. Accordingly, when randomly selected (i.e., scattered) semiconductor chips are to be EDS tested in order to achieve statistical objectivity of data indicating characteristics of the wafer, the test must be repeatedly performed.

### SUMMARY OF THE INVENTION

In accordance with the present invention there are provided a probe card and a method for testing semiconductor chips using the probe card, which are capable of selecting semiconductor chips on a wafer and EDS testing them at the same time to achieve statistical objectivity of data indicating characteristics of the wafer.

Also in accordance with the present invention there are provided a probe card and a method for testing semiconductor chips using the probe card, which are capable of EDS testing a number of semiconductor chips gathered in one area on a wafer and a number of arbitrarily selected semiconductor chips at the same time.

Also in accordance with the present invention there are provided a probe card and a method for testing semiconductor chips using the probe card, which are capable of shortening EDS test time to test a plurality of semiconductor chips gathered in one area on a wafer or scattered on the wafer.

In accordance with one particular aspect of the present invention, provided is a probe card for test of semiconductor chips, the probe card comprising: a circuit board including a plurality of contact pads configured to receive an electrical signal for testing electrical characteristics of the semiconductor chips; and a fixing plate configured to secure the circuit board, the fixing plate including a plurality of probe blocks, wherein a set of probe blocks from the plurality of probe blocks is configured to be selected based on a number and a position within the plurality of the probe blocks embodied in a probe block selection signal from a test head of a tester configured to EDS test the semiconductor chips.

Each probe block can comprise a probe needle configured to apply an electrical signal to a probing pad of a corresponding semiconductor chip.

The probe card can further comprise a switching matrix configured to receive the probe block selection signal from the tester head and to determine the set of probe blocks from the number and position.

The plurality of probe blocks can be arranged in a rectangular shape.

The plurality of probe blocks can be arranged in one of a +, =, ∥, X, ◯, or ▴ shape.

The selected set of probe blocks can be in a central area of the probe card.

The selected set of probe blocks can be arranged in a central area and in up/down/left/right directions from the central area of the probe card.

The selected set of probe blocks can be arranged in a vertical direction.

The selected set of probe blocks can be arranged in a horizontal direction.

In accordance with another aspect of the present invention, provided is a method for testing semiconductor chips using a probe card, the method comprising: receiving, from a test head of a tester configured for EDS testing the semiconductor chips on a wafer, a signal for determining a number and a position of probe blocks to be activated, by a switching matrix of the probe card having a plurality of probe blocks; selecting, by the switching matrix, a set of probe blocks from the plurality of probe blocks based on the number and the position indicated in the signal from the tester head; and performing the EDS test on a plurality of semiconductor chips at positions corresponding to the selected set of probe blocks in a one-step process using the selected set of probe blocks.

Performing the EDS test of a semiconductor chip can include applying an electrical signal generated from the tester to a probe needle of a corresponding probe block in the set of probe blocks.

The plurality of probe blocks can be arranged in a rectangular shape.

The plurality of probe blocks are arranged in one of a +, =, ∥, X, ◯, or ▴ shape.

The selected set of probe blocks can be gathered in a central area.

The selected set of probe blocks can be arranged in a central area and in up/down/left/right directions from the central area.

The selected set of probe blocks can be arranged in a vertical direction.

The selected set of probe blocks can be arranged in a horizontal direction.

In accordance with yet another aspect of the invention, provided is a probe card configured for testing semiconductor chips, the probe card comprising: a circuit board including a plurality of contact pads configured to receive an electrical signal for testing electrical characteristics of the semiconductor chips; a fixing plate configured to secure the circuit board, the fixing plate including a plurality of probe blocks, each probe block comprising a probe needle configured to apply the electrical signal to a probe pad of a corresponding one of the semiconductor chips when said probe block is selected; and a switching matrix configured to select a set of probe blocks from the plurality of probe blocks based on a number and a position within the plurality of probe blocks embodied in a probe block selection signal received from a test head of a tester configured to EDS test the semiconductor chips.

The plurality of probe blocks can comprise a matrix of individually selectable probe blocks.

The probe card can be configured for one-step EDS testing.

### BRIEF DESCRIPTION OF THE DRAWINGS

The present invention will become more apparent in view of the attached drawings and accompanying detailed description. The embodiments depicted therein are provided by way of example, not by way of limitation. In the drawings:

FIG. 1 illustrates a conventional single-type probe card in accordance with the prior art;

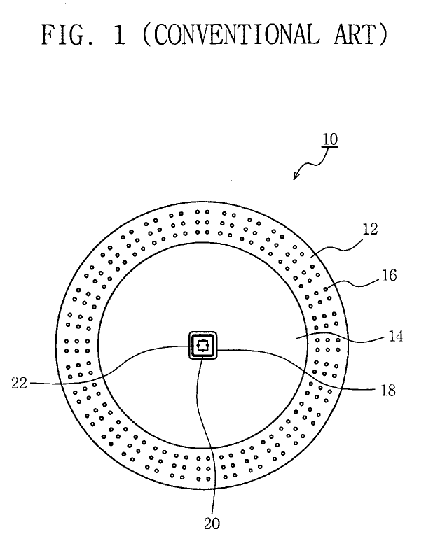

FIG. 2 illustrates a conventional multi-type probe card in accordance with the prior art;

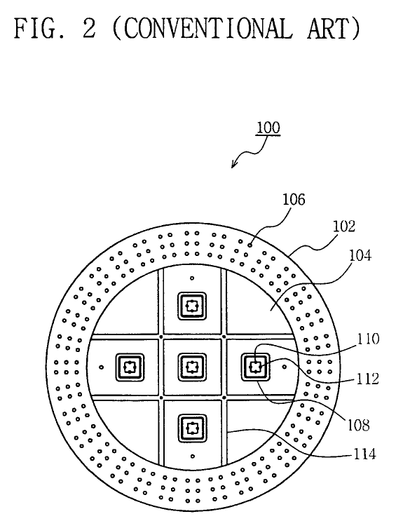

FIG. 3 illustrates an embodiment of a probe card according to a first aspect of the present invention;

FIGS. 4A and 4B illustrate embodiments of arrangements of probe blocks when five semiconductor chips in a central area of a wafer are EDS tested;

FIGS. 5A and 5B illustrate embodiments of probe block arrangements when five semiconductor chips in a central area of a wafer and in up/down/left/right directions from the central area are EDS tested;

FIGS. 6A and 6B illustrate embodiments of probe block arrangements when five semiconductor chips vertically arranged in a wafer are EDS tested;

FIGS. 7A and 7B illustrate embodiments of probe block arrangements when five semiconductor chips horizontally arranged in a wafer are EDS tested;

FIG. 8 illustrates an embodiment of a probe card according to a second aspect of the present invention;

FIGS. 9A and 9B illustrate embodiments of arrangements of probe blocks when five semiconductor chips in a central area of a wafer are EDS tested;

FIGS. 10A and 10B illustrate embodiments of probe block arrangements when five semiconductor chips in a central area of a wafer and in up/down/left/right directions from the central area are EDS tested; and

FIG. 11 is a flowchart illustrating an embodiment of a method for testing semiconductor chips using a probe card in accordance with the present invention.

### DETAILED DESCRIPTION OF THE INVENTION

Embodiments in accordance with the present invention will now be described more fully hereinafter with reference to the accompanying drawings. This invention can, however, be embodied in different forms and should not be construed as limited to the embodiments set forth herein. In the drawings like numbers refer to like elements.

It will be understood that, although the terms first, second, etc. may be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

It will be understood that when an element is referred to as being “on” or “connected” or “coupled” to another element, it can be directly on or connected or coupled to the other element or intervening elements may be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

To check electrical characteristics of a semiconductor chip, the probe needle of the probe card is brought into contact with a probing pad of the semiconductor chip, and current (electrical signal) for measurement is supplied via the probe needle. A semiconductor chip determined as being good through test using the probe card is packaged into a final product.

It is common to employ single test equipment for testing a single chip using a single-type probe card, as test equipment used upon product analysis in a wafer test step. However, there is a recently increasing need for a technique of testing a plurality of chips distributed throughout a wafer in order to achieve statistical objectivity of data indicating characteristics of the wafer. When the single-type probe card is used to test a plurality of distributed semiconductor chips, the test must be repeatedly performed by the number of the semiconductor chips, increasing test time and greatly degrading equipment efficiency. To solve these problems, a multi-type probe card capable of testing a plurality of semiconductor chips at the same time has been used. This multi-type probe card has an advantage of short EDS test time in comparison with a single-type probe card, but is allowed to test only a plurality of semiconductor chips at a defined position. Accordingly, this type of multi-type probe card is less efficient in arbitrarily selecting and EDS testing a plurality of chips distributed throughout a wafer in order to achieve statistical objectivity of data indicating characteristics of the wafer.

Accordingly, the present invention provides a probe card and a method for test of semiconductor chips using the probe card, which are capable of EDS testing a number of semiconductor chips on a wafer and a number of arbitrarily selected semiconductor chips at substantially the same time to achieve statistical objectivity of data indicating characteristics of the wafer.

A probe card for test of semiconductor chips and a method for test of semiconductor chips using the probe card according to the present invention will now be described more fully hereinafter with reference to the accompanying drawings,

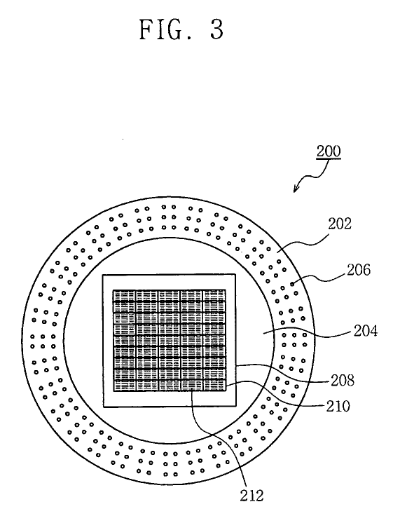

FIG. 3 illustrates an embodiment of a probe card 200 according to a first aspect of the present invention.

Referring to FIG. 3, the probe card 200 comprises a circuit board 202, and a fixing plate 204 for securing the circuit board 202. The circuit board 202 comprises a plurality of contact pads 206. The fixing plate 204 comprises a probe area 208 including the plurality of probe blocks 210. Each probe block in the plurality of probe blocks 210 comprises a probe needle 212 for applying an electrical signal to a semiconductor chip.

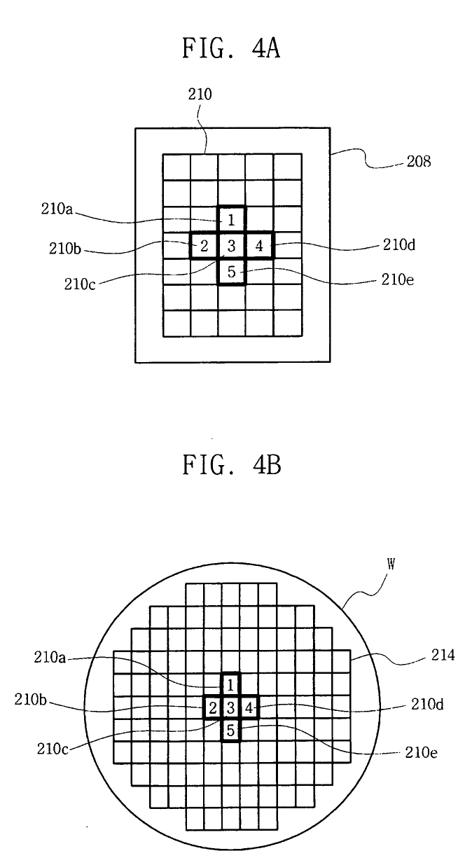

In this embodiment, the plurality of probe blocks 210 takes the form of a rectangular matrix of probe blocks arranged in horizontal and vertical directions within the probe area 208, as shown in FIG. 3, and only probe blocks corresponding to semiconductor chips to be EDS tested are selected from the plurality of probe blocks 210 (which will be described in FIGS. 4A to 7B). One-step EDS test of the semiconductor chips corresponding to the selected probe blocks is then performed using the probe blocks. As the selected semiconductor chips are EDS tested using the one-step process, EDS test time can be shortened and equipment efficiency is improved, and statistical objectivity of data indicating characteristics of the wafer can be effectively achieved.

FIGS. 4A, 5A, 6A and 7A illustrate arrangements of selected ones of the probe blocks in the probe card as shown in FIG. 3. FIGS. 4B, 5B, 6B, and 7B illustrate arrangements of the selected probe blocks on a wafer.

First, an arrangement of probe blocks corresponding to five semiconductor chips in a central area of a wafer W that are to be EDS tested are shown in FIGS. 4A and 4B.

When the five semiconductor chips in the central area of the wafer W are to be EDS tested, probe blocks 210a, 210b, 210c, 210d, and 210e in a central area of the rectangular plurality of probe blocks 210 are selected, as shown in FIG. 4A. In this case, the probe blocks 210a, 210b, 210c, 210d, and 210e are selected in response to a signal for determining the number (parallel number) and position of probe blocks to be activated (i.e., a signal for selecting the number and position of a plurality of probe blocks in the probe card 200), which is received from a tester head via a switching matrix on the probe card.

The wafer W having a plurality of semiconductor chips formed thereon is then aligned between the plurality of probe blocks 210 and the tester, as shown in FIG. 4B. The selected probe blocks 210a to 210e are placed in one-to-one correspondence with the five semiconductor chips in the central area of a wafer cell area 214 of wafer W. After the selected probe blocks 210a to 210e are placed on the semiconductor chips in the central area of the wafer to be EDS tested, an electrical signal generated from the tester is applied to the probe needle (not shown) of each selected probe block. The probe needle is then brought into contact with a probing pad on the semiconductor chip to deliver the electrical signal from the tester to the semiconductor chip. Finally, the five semiconductor chips in the central area of the wafer W are EDS tested, at substantially the same time.

As described above, when the semiconductor chips in the central area of the wafer are to be EDS tested, the probe blocks at the positions corresponding to the semiconductor chips are selected from the rectangular plurality of probe blocks 210. As a result, the semiconductor chips in the central area of the wafer can be EDS tested in one-step process by the selected probe blocks.

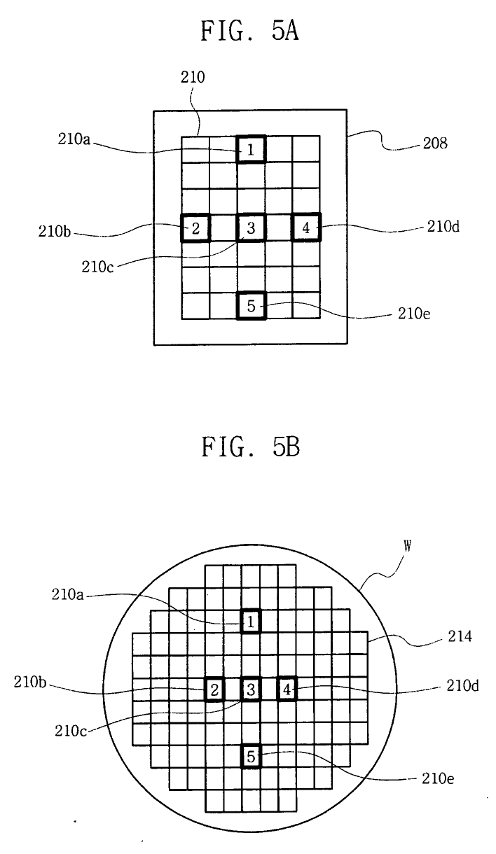

FIGS. 5A and 5B illustrate probe block arrangements when five semiconductor chips in a central area of a wafer and in up/down/left/right directions from the central area are to be EDS tested.

When five semiconductor chips in the central area of the wafer and in up/down/left/right directions from the central area of wafer W are to be EDS tested, probe blocks 210a, 210b, 210c, 210d, and 210e corresponding to positions of the five semiconductor chips in the rectangular plurality of probe blocks 210 are selected as shown in FIG. 5A. In this case, the probe blocks 210a, 210b, 210c, 210d, and 210e are selected in response to a signal for determining the number (parallel number) and position of probe blocks to be activated (i.e., a signal for selecting the number and position of a plurality of probe blocks in the probe card 208), which is received from a tester head via a switching matrix.

The wafer W having a plurality of semiconductor chips formed thereon is then aligned between the plurality of probe blocks 210 and the tester, as shown in FIG. 5B. The selected probe blocks 210a to 210e are placed in one-to-one correspondence with the five semiconductor chips in the central area and in up/down/left/right directions from the central area of the wafer cell area 214. After the selected probe blocks 210a to 210e are placed on the semiconductor chips in the central area of the wafer to be EDS tested, an electrical signal generated from the tester is applied to the probe needle (not shown) of each probe block. The probe needle is then brought into contact with a probing pad on the semiconductor chip to deliver the electrical signal from the tester to the semiconductor chip. Finally, the five semiconductor chips in the central area of the wafer are EDS tested, at the same time.

As described above, when the semiconductor chips in the central area of the wafer and in up/down/left/right directions from the central area of wafer W are to be EDS tested, the probe blocks at the positions corresponding to the semiconductor chips are selected from the rectangular plurality of probe blocks 210. As a result, the semiconductor chips in the central area of the wafer and in up/down/left/right directions from the central area can be EDS tested in a one-step process by the selected probe blocks.

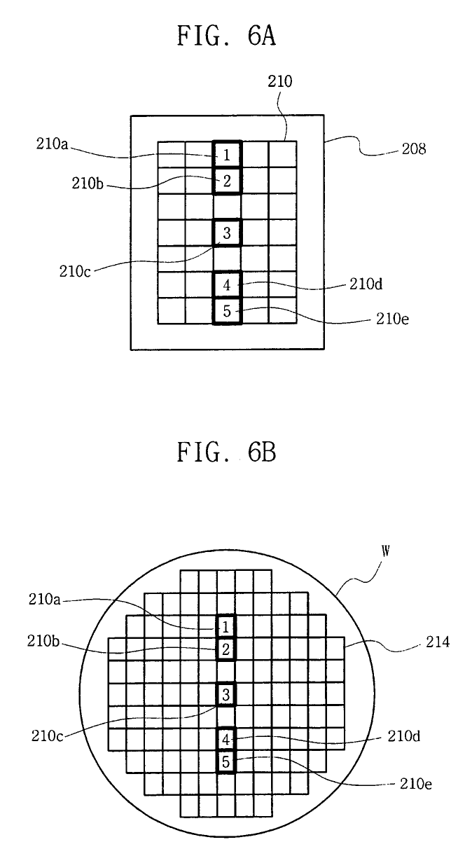

FIGS. 6A and 6B illustrate probe block arrangements when five semiconductor chips vertically arranged in a wafer are to be EDS tested.

When five semiconductor chips vertically arranged on wafer W are to be EDS tested, probe blocks 210a, 210b, 210c, 210d, and 210e corresponding to positions of the semiconductor chips in the rectangular plurality of probe blocks 210 are selected as shown in FIG. 6A. In this case, the probe blocks 210a, 210b, 210c, 210d, and 210e are selected in response to a signal for determining the number (parallel number) and position of probe blocks to be activated (i.e., a signal for selecting the number and position of a plurality of probe blocks in the probe card 208), which is received from a tester head via a switching matrix.

The wafer W having a plurality of semiconductor chips formed thereon is then aligned between the plurality of probe blocks 210 and the tester, as shown in FIG. 6B. The selected probe blocks 210a to 210e are placed in one-to-one correspondence with the five semiconductor chips vertically arranged on the wafer cell area 214. After the selected probe blocks 210a to 210e are placed on the semiconductor chips to be EDS tested, an electrical signal generated from the tester is applied to the probe needle (not shown) of each selected probe block. The probe needle is then brought into contact with a probing pad on the semiconductor chip to deliver the electrical signal from the tester to the semiconductor chip. Accordingly, the five semiconductor chips vertically arranged on the wafer are EDS tested, at substantially the same time.

As described above, when the semiconductor chips vertically arranged on the wafer are to be EDS tested, the probe blocks at the positions corresponding to the semiconductor chips are selected from the rectangular plurality of probe blocks 210. As a result, the five semiconductor chips vertically arranged on the wafer can be EDS tested in one-step process by the selected probe blocks.

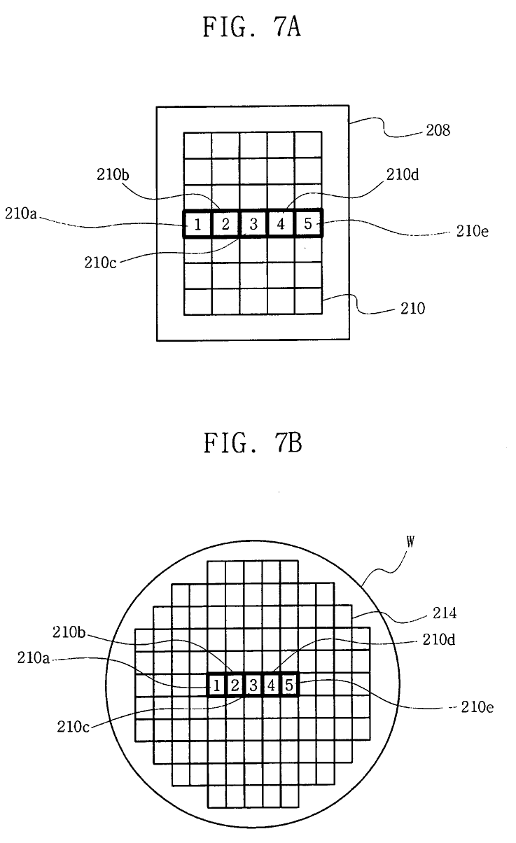

FIGS. 7A and 7B illustrate probe block arrangements when five semiconductor chips horizontally arranged in a wafer are to be EDS tested.

When five semiconductor chips horizontally arranged on the wafer are to be EDS tested, probe blocks 210a, 210b, 210c, 210d, and 210e corresponding to positions of the five semiconductor chips in the rectangular plurality of probe blocks 210 are selected as shown in FIG. 7A. In this case, the probe blocks 210a, 210b, 210c, 210d, and 210e are selected in response to a signal for determining the number (parallel number) and position of probe blocks to be activated (i.e., a signal for selecting the number and position of a plurality of probe blocks in the probe card), which is received from a tester head via a switching matrix.

The wafer W having a plurality of semiconductor chips formed thereon is then aligned between the plurality of probe blocks 210 and the tester, as shown in FIG. 7B. The selected probe blocks 210a to 210e are placed in one-to-one correspondence with the five semiconductor chips horizontally arranged on the wafer cell area 214. After the selected probe blocks 210a to 210e are placed on the semiconductor chips to be EDS tested, an electrical signal generated from the tester is applied to the probe needle (not shown) of each selected probe block. The probe needle is then brought into contact with a probing pad on the semiconductor chip to deliver the electrical signal from the tester to the semiconductor chip. Accordingly, the five semiconductor chips horizontally arranged on the wafer are EDS tested, at substantially the same time.

As described above, when the semiconductor chips horizontally arranged on the wafer are to be EDS tested, the probe blocks at the positions corresponding to the semiconductor chips are selected from the rectangular plurality of probe blocks 210. As a result, the five semiconductor chips horizontally arranged on the wafer can be EDS tested in one-step process by the selected probe blocks.

In the embodiments of the present invention described in FIGS. 4A to 7B, the semiconductor chips at specific positions on the wafer are first selected, and the probe blocks in areas corresponding to the positions of the semiconductor chips are selected. However, in other embodiments probe blocks at specific positions in the rectangular probe block can be selected and then semiconductor chips at positions corresponding to the selected probe blocks can be EDS tested, instead of first selecting the semiconductor chips to be EDS tested. Those skilled in the art will also appreciate that while five semiconductor chips and probe blocks were used in the above illustrative embodiments, the present invention is not so limited.

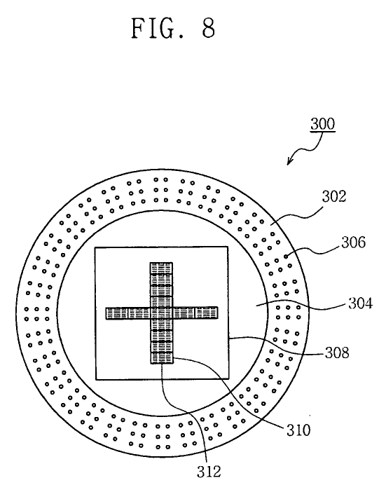

FIG. 8 illustrates another embodiment of a probe card 300 according to a second aspect of the present invention.

Referring to FIG. 8, the probe card 300 comprises a circuit board 302, and a fixing plate 304 for securing the circuit board. The circuit board 302 comprises a plurality of contact pads 306. The fixing plate 304 comprises a probe area 308 including a plurality of probe blocks 310 arranged in a cross (or “+”) shape. Each of the probe blocks 310 comprises a probe needle 312 for applying an electrical signal to a semiconductor chip.

In the present invention, the plurality of probe blocks 210 are arranged in a cross (or “+”) shape in the probe area 208 as shown in FIG. 8, and only probe blocks corresponding to semiconductor chips to be EDS tested are selected from the plurality of probe blocks 210. One-step EDS test of the semiconductor chips corresponding to the selected probe blocks is then performed using the probe blocks.

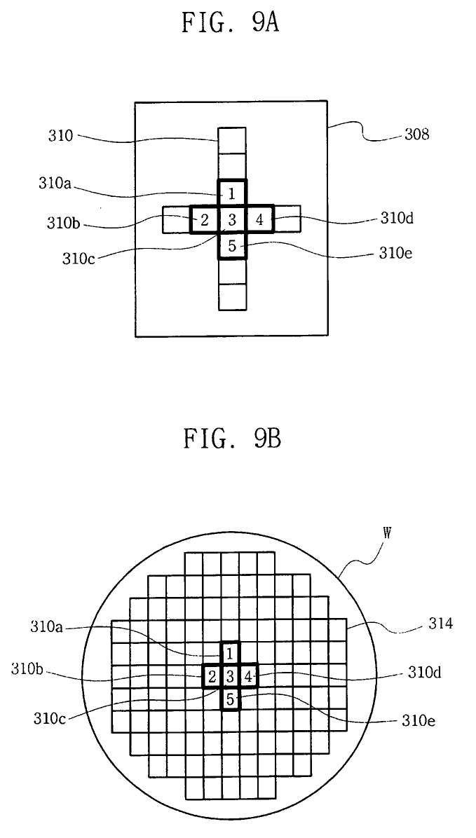

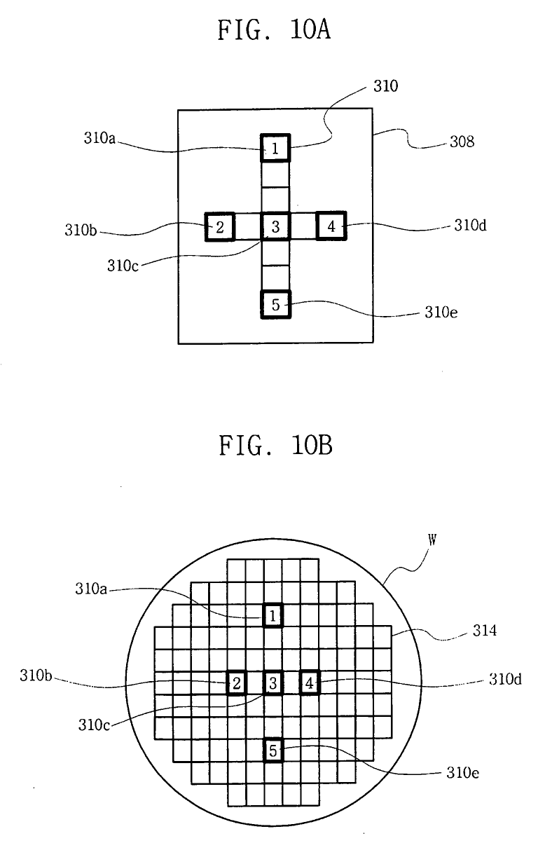

FIGS. 9A and 10A illustrate arrangements of selected ones of the probe blocks in the probe card 300 as shown in FIG. 8. FIGS. 9B and 10B illustrate arrangements of the selected probe blocks on a wafer.

First, arrangements of probe blocks when five semiconductor chips in a central area of a wafer are to be EDS tested are shown in FIGS. 9A and 9B.

When the five semiconductor chips in the central area of the wafer W are to be EDS tested, probe blocks 310a, 310b, 310c, 310d, and 310e in a central area of the cross-shaped plurality of probe blocks 310 are selected, as shown in FIG. 9A. In this case, the probe blocks 310a, 310b, 310c, 310d, and 310e are selected in response to a signal for determining the number (parallel number) and position of probe blocks to be activated (i.e., a signal for selecting the number and position of a plurality of probe blocks in the probe card 308), which is received from a tester head via a switching matrix.

The wafer W having a plurality of semiconductor chips formed thereon is then aligned between the plurality of probe blocks 310 and the tester, as shown in FIG. 9B. The selected probe blocks 310a to 310e are placed in one-to-one correspondence with the five semiconductor chips in the central area of the wafer cell area 314. After the selected probe blocks 310a to 310e are placed on the semiconductor chips in the central area of the wafer W to be EDS tested, an electrical signal generated from the tester is applied to the probe needle (not shown) of each selected probe block. The probe needle is then brought into contact with a probing pad on the semiconductor chip to deliver the electrical signal from the tester to the semiconductor chip. Finally, the five semiconductor chips in the central area of the wafer are EDS tested, at substantially the same time.

As described above, when the semiconductor chips in the central area of the wafer W are to be EDS tested, the probe blocks at the positions corresponding to the semiconductor chips are selected from the cross-shaped plurality of probe blocks 310. As a result, the semiconductor chips in the central area of the wafer can be EDS tested in one-step process by the selected probe blocks.

FIGS. 10A and 10B illustrate probe block arrangements when five semiconductor chips in a central area of a wafer and in up/down/left/right directions from the central area are to be EDS tested.

When five semiconductor chips in the central area of the wafer and in up/down/left/right directions from the central area of wafer W are to be EDS tested, probe blocks 310a, 310b, 310c, 310d, and 310e corresponding to positions of the semiconductor chips in the cross-shaped plurality of probe block 310 are selected as shown in FIG. 10A. In this case, the probe blocks 310a, 310b, 310c, 310d, and 310e are selected in response to a signal for determining the number (parallel number) and position of probe blocks to be activated (i.e., a signal for selecting the number and position of a plurality of probe blocks in the probe card 300), which is received from a tester head via a switching matrix.

The wafer W having a plurality of semiconductor chips formed thereon is then aligned between the plurality of probe blocks 310 and the tester, as shown in FIG. 10B. The selected probe blocks 310a to 310e are placed in one-to-one correspondence with the five semiconductor chips in the central area of the wafer cell area 314 and in up/down/left/right directions from the central area in the wafer cell area 314. After the selected probe blocks 310a to 310e are placed on the semiconductor chips in the central area of the wafer W to be EDS tested, an electrical signal generated from the tester is applied to the probe needle (not shown) of each probe block. The probe needle is then brought into contact with a probing pad on the semiconductor chip to deliver the electrical signal from the tester to the semiconductor chip. Finally, the five semiconductor chips in the central area of the wafer and in up/down/left/right directions from the central area are EDS tested, at substantially the same time.

As described above, when the semiconductor chips in the central area of the wafer and in up/down/left/right directions from the central area of wafer W are to be EDS tested, the probe blocks at the positions corresponding to the semiconductor chips are selected from the cross-shaped plurality of probe blocks 210. As a result, the semiconductor chips in the central area of the wafer and in up/down/left/right directions from the central area can be EDS tested in one-step process by the selected probe blocks.

In the embodiments of the present invention described in FIGS. 9A to 10B, the semiconductor chips at specific positions on the wafer are first selected, and the probe blocks in areas corresponding to the positions of the semiconductor chips are selected. However, probe blocks at specific positions in the cross-shaped plurality of probe blocks can be selected and then semiconductor chips at positions corresponding to the selected probe blocks can be EDS tested, instead of first selecting the semiconductor chips to be EDS tested.

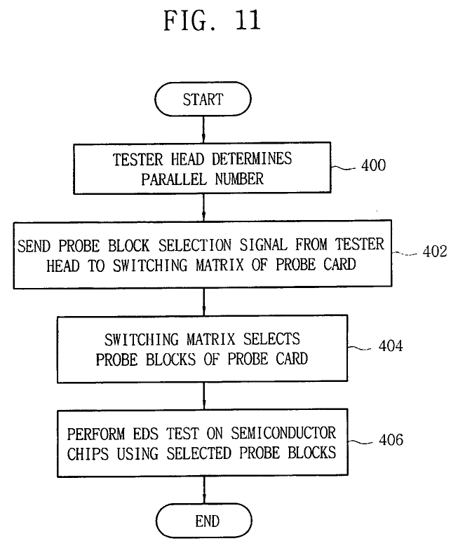

FIG. 11 is a flowchart illustrating an embodiment of a method for testing semiconductor chips using a probe card in accordance with the present invention.

Referring to FIG. 11, a tester head for the tester for performing the EDS test on semiconductor chips determines a probe block number (parallel number) required for wafer analysis (Step 400). A signal for selecting the number and position of the probe blocks in the probe card according to the probe block number determined by the tester head is then sent from the tester head to the switching matrix (Step 402).

Then, the switching matrix selects any of the plurality of probe blocks in the probe card in response to the probe block selection signal from the tester head (Step 404). The semiconductor chips at positions corresponding to the selected probe blocks are EDS tested using the probe blocks (Step 406).

In this manner, in accordance with the present invention, the tester head determines the parallel number required for wafer analysis, and any of the plurality of probe blocks in the probe card are selected by the probe block selection signal from the tester head. The semiconductor chips at the positions corresponding to the selected probe blocks are then EDS tested in one-step process using the probe blocks. Thus, a number of semiconductor chips can be rapidly EDS tested.

As described above, in implementing the probe card for electrically testing semiconductor chips according to the present invention, the probe blocks corresponding to the selected ones of the semiconductor chips on the wafer can be selected so that the selected semiconductor chips are EDS tested in one-step process. As the selected semiconductor chips are EDS tested in one-step process, EDS test time can be shortened so that equipment efficiency is improved, and statistical objectivity of data indicating characteristics of the wafer can be effectively achieved. Thus, development time of new products can be greatly shortened.

The invention has been described using preferred exemplary embodiments. However, it is to be understood that the scope of the invention is not limited to the disclosed embodiments. For example, the probe block can have any of a variety of shapes (e.g., a, =, ∥, X, ◯, or ▴ shape), in addition to the rectangular shape of the first embodiment or the cross shape of the second embodiment.

On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements. Thus, it is intended by the following claims to claim that which is literally described and all equivalents thereto, including all modifications and variations that fall within the scope of each claim.

What is claimed is:

1. A probe card configured for testing semiconductor chips, the probe card comprising:
a circuit board including a plurality of contact pads configured to receive an electrical signal for testing electrical characteristics of the semiconductor chips; and
a fixing plate configured to secure the circuit board, the fixing plate including a plurality of probe blocks, wherein a set of probe blocks from the plurality of probe blocks is configured to be selected based on a number and a position within the plurality of probe blocks embodied in a probe block selection signal from a test head of a tester configured to EDS test the semiconductor chips.

2. The probe card according to claim 1, wherein each probe block comprises a probe needle configured to apply an electrical signal to a probing pad of a corresponding semiconductor chip.

3. The probe card according to claim 1, wherein the probe card further comprises:
a switching matrix configured to receive the probe block selection signal from the tester head and to determine the set of probe blocks from the number and position.

4. The probe card according to claim 1, wherein the plurality of probe blocks are arranged in a rectangular shape.

5. The probe card according to claim 1, wherein the plurality of probe blocks are arranged in one of a +, =, ∥, X, ◯, or ▴ shape.

6. The probe card according to claim 1, wherein the selected set of probe blocks are in a central area of the probe card.

7. The probe card according to claim 1, wherein the selected set of probe blocks are arranged in a central area and in up/down/left/right directions from the central area of the probe card.

8. The probe card according to claim 1, wherein the selected set of probe blocks are arranged in a vertical direction.

9. The probe card according to claim 1, wherein the selected set of probe blocks are arranged in a horizontal direction.

10. A method for testing semiconductor chips using a probe card, the method comprising:
receiving, from a test head of a tester configured for EDS testing the semiconductor chips on a wafer, a signal for determining a number and a position of probe blocks to be activated, by a switching matrix of the probe card having a plurality of probe blocks;
selecting, by the switching matrix, a set of probe blocks from the plurality of probe blocks based on the number and the position indicated in the signal from the test head; and
performing the EDS test on a plurality of semiconductor chips at positions corresponding to the selected set of probe blocks in a one-step process using the selected set of probe blocks.

11. The method according to claim 10, wherein performing the EDS test of a semiconductor chip includes applying an electrical signal generated from the tester to a probe needle of a corresponding probe block in the set of probe blocks.

12. The method according to claim 10, wherein the plurality of probe blocks are arranged in a rectangular shape.

13. The method according to claim 10, wherein the plurality of probe blocks are arranged in one of a +, =, ∥, X, ◯, or ▴ shape.

14. The method according to claim 10, wherein the selected set of probe blocks are gathered in a central area.

15. The method according to claim 10, wherein the selected set of probe blocks are arranged in a central area and in up/down/left/right directions from the central area.

16. The method according to claim 10, wherein the selected set of probe blocks are arranged in a vertical direction.

17. The method according to claim 10, wherein the selected set of probe blocks are arranged in a horizontal direction.

18. A probe card configured for testing semiconductor chips, the probe card comprising:
a circuit board including a plurality of contact pads configured to receive an electrical signal for testing electrical characteristics of the semiconductor chips;
a fixing plate configured to secure the circuit board, the fixing plate including a plurality of probe blocks, each probe block comprising a probe needle configured to apply the electrical signal to a probe pad of a corresponding one of the semiconductor chips when said probe block is selected; and
a switching matrix configured to select a set of probe blocks from the plurality of probe blocks based on a number and a position within the plurality of probe blocks embodied in a probe block selection signal received from a test head of a tester configured to EDS test the semiconductor chips.

19. The probe card of claim 18, wherein the plurality of probe blocks comprises a matrix of individually selectable probe blocks.

20. The probe card of claim 18, wherein the probe card is configured for one-step EDS testing.
